(19) United States
(12) Patent Application Publication
(10) Pub. No.: US 2017/0167092 A1
(43) Pub. Date: Jun. 15, 2017

(54) Method for electric power construction warning and device thereof

(71) Applicant: SINADENG CLOTHING(HONGKONG) LIMITED, Hongkong (CN)

(72) Inventor: Zebiao Lin, Hongkong (CN)

(73) Assignee: SINADENG CLOTHING(HONGKONG) LIMITED

(21) Appl. No.: 15/442,712

(22) Filed: Feb. 27, 2017

(51) Int. Cl. E01F 9/692; G08B 21/02; B60T 7/04; H01L 31/14; E01F 13/02; B60T 1/00

(52) U.S. Cl. CPC E01F 9/692; E01F 13/028; E01F 13/022; B60T 1/005; B60T 7/04; H01L 31/14; G08B 21/02

(57) ABSTRACT

A device for electric power construction warning includes: a guardrail body, a caution light and a second hook, wherein a mobile firmware is provided under the guardrail body; the caution light is provided on a top of the guardrail body, and is covered by a shell; a solar power unit is provided on a top of the shell, and is connected to the caution light; a pair of handles are symmetrically provided on external faces at a top portion of the guardrail body; a first ring is provided on an external face at a bottom portion of the guardrail body; two roller supports are separately provided on a left side of the guardrail body, and a roller is provided on each of the roller supports; a second ring is provided on a right side of the firmware to cooperate with the second hook on a left side of the firmware.

### BACKGROUND OF THE PRESENT INVENTION

Field of Invention

The present invention relates to a field of electric power, and more particularly to a method for electric power construction warning and a device thereof

Description of Related Arts

With the development of society, electricity also experienced rapid development. People's demands for as well as dependence on electricity are increasing, and people want to have qualified and uninterrupted power supply services. Therefore, power repair and maintenance have been increasingly important. In the construction of electric power repair, only construction workers with full power safety knowledge know how to prevent electric shock. Unfortunately, during construction, many passers-by will unconsciously get close to the charged equipment under the impact of curiosity, bringing security risks. Therefore, the construction should be accompanied with safety warning or guardrail, in order to keep the passers-by away. Conventional guardrails are large, and are difficult to transport with a huge number.

### SUMMARY OF THE PRESENT INVENTION

An object of the present invention is to provide a method for electric power construction warning and a device thereof, with a simple structure and convenient construction.

Accordingly, in order to accomplish the above object, the present invention provides a method for electric power construction warning and a device thereof, comprising: a guardrail body, a caution light and a second hook, wherein a mobile firmware is provided under the guardrail body; the caution light is provided on a top of the guardrail body, and is covered by a shell; a solar power unit is provided on a top of the shell, and is connected to the caution light; a pair of handles are symmetrically provided on external faces at a top portion of the guardrail body; a first ring is provided on an external face at a bottom portion of the guardrail body; two roller supports are separately provided on a left side of the guardrail body, and a roller is provided on each of the roller supports; a warning strip is wound on the roller, and one end of the warning strip is connected to a first hook through a connecting belt; a second ring is provided on a right side of the firmware; the second hook is vertically arranged with an opening thereof facing downwards, and the second ring is horizontally arranged.

Preferably, the second ring cooperates with the second hook for connection.

Preferably, the caution light comprises a switch.

The method for the electric power construction warning comprises steps of: providing a mobile firmware under a base of each of guardrail bodies; connecting a second ring of the mobile firmware to a second hook of an adjacent mobile firmware, in such a manner that the guardrail bodies are integrated and move as a whole; providing universal wheels under the mobile firmware for moving the guardrail bodies, and providing a foot break on each of the universal wheels for fixing the guardrail bodies; and isolating a construction site by pulling out two warning strips respectively wound on two separate rollers at a left side of each of the guardrail bodies and connecting the warning strips to an adjacent guardrail body.

Compared with conventional technologies, the present invention has a simple structure and is easy to use. The second hook and the second ring on the firmware are tough and connected, in such a manner that the guardrail bodies are integrated. The second hook is vertically arranged with an opening thereof facing downwards, and the second ring is horizontally arranged. As a result, for connecting or disconnecting the guardrail bodies, only the side where the second hook is placed needs to be slightly lifted, and then the second hook is directly connected to or disconnected from the second ring. The universal wheels are provided under the mobile firmware for moving the guardrail bodies as a whole, which solves technical problems such as rapid disconnection or connection, and convenient transportation.

Compared with conventional technologies, the warning strips may be connected to the adjacent guardrail body by workers in advance, then the guardrail bodies are arranged along a desired route, so as to reduce labor for repeatedly pulling the warning to strips and repeatedly moving the guardrail bodies, which improve working efficiency.

The caution light is provided for enhancing a caution effect.

These and other objectives, features, and advantages of the present invention will become apparent from the following detailed description, the accompanying drawings, and the appended claims.

### BRIEF DESCRIPTION OF THE DRAWINGS

FIG. 1 is a sketch view of a method for electric power construction warning and a device thereof.

### DETAILED DESCRIPTION OF THE PREFERRED EMBODIMENT

Referring to the drawing, the present invention is further illustrated.

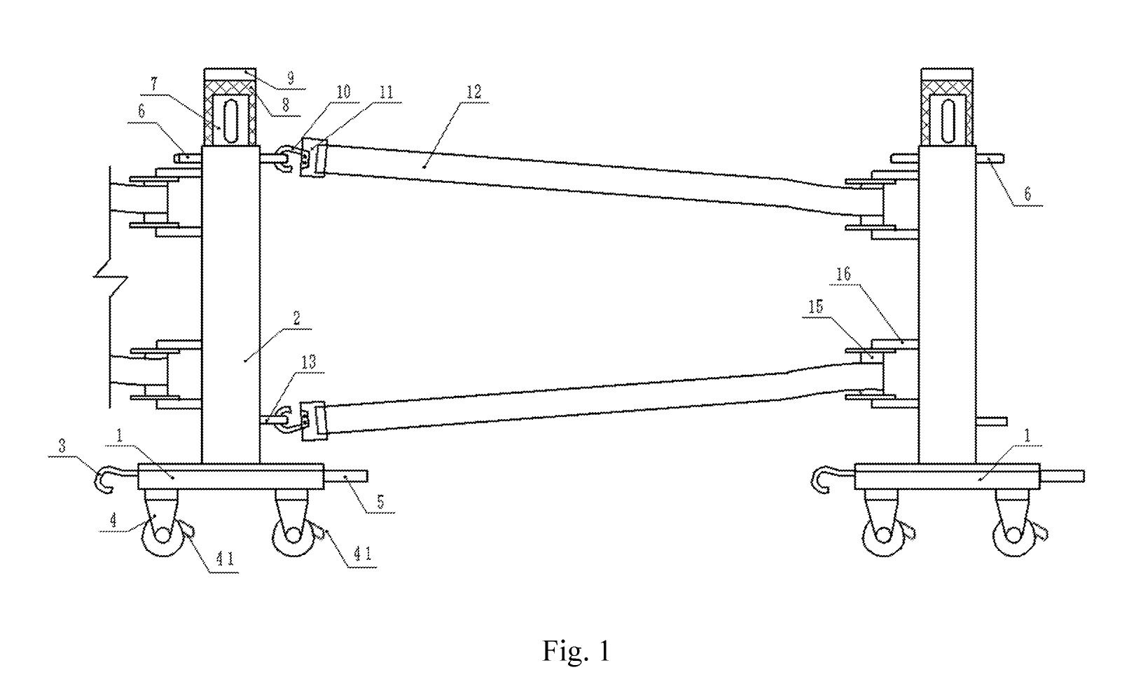

Referring to FIG. 1, a method for electric power construction warning and a device thereof comprise: a guardrail body 2, a caution light 7 and a second hook 3, wherein a mobile firmware 1 is provided under the guardrail body 2; the caution light 7 is provided on a top of the guardrail body 2, and is covered by a shell 8; a solar power unit 9 is provided on a top of the shell 8, and is connected to the caution light 7; a pair of handles 6 are symmetrically provided on external faces at a top portion of the guardrail body 2 for lifting the guardrail bodies 2 by worker hands, in such a manner that the device is able to be easily installed or transported; a first ring 13 is provided on an external face at a bottom portion of the guardrail body 2; two roller supports 16 are separately provided on a left side of the guardrail body 2, and a roller 15 is provided on each of the roller supports 16; a warning strip 12 is wound on the roller 15, and one end of the warning strip 12 is connected to a first hook 10 through a connecting belt 11;

during working, two guardrail bodies 2 are placed with an interval; the upper first hook 10 of the right guardrail body 2 is connected to one of the handles 6 of the left guardrail body 2, and the lower first hook 10 of the right guardrail body 2 is connected to the first ring 13 of the left guardrail body 2; the warning strips 12 are used as a guardrail, and the caution light 7 is turned on for warning; the second hook 3 is provided on a left side of the firmware 1 and a second ring 5 is provided on a right side of the firmware 1; the second hook 3 is vertically arranged with an opening thereof facing downwards, and the second ring 5 is horizontally arranged; the second ring 5 cooperates with the second hook 3 for connection; four universal wheels 4 are arranged under the mobile firmware 1, and each of the universal wheels 4 comprises a foot break 41; during working, the universal wheels 4 are used for moving the guardrail bodies 2, wherein after step down the foot break 41, the universal wheels are fixed, and the foot break 41 should be loosened for moving the guardrail bodies 2 again, which is convenient and saves effort; for moving a plurality of the guardrail bodies 2, the second rings 5 and the second hooks 3 of the guardrail bodies 2 are connected in sequence, in such a manner that the guardrail bodies 2 are integrated and move as a whole.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A method for electric power construction warning, comprising steps of:
providing a mobile firmware (1) under a base of each of guardrail bodies (2), so as to freely move the guardrail bodies (2); connecting a second ring (5) of the mobile firmware (1) to a second hook (3) of an adjacent mobile firmware (1), in such a manner that the guardrail bodies (2) are integrated and move as a whole; and isolating a construction site by pulling out two warning strips (12) respectively wound on two separate rollers (15) at a left side of each of the guardrail bodies (2) and connecting the warning strips (12) to an adjacent guardrail body (2).

2. The method, as recited in claim 1, wherein the second hook (3) is vertically arranged with an opening thereof facing downwards, and the second ring (5) is horizontally arranged.

3. The method, as recited in claim 1, wherein the warning strips (12) are connected to the adjacent guardrail body (2) before placing the guardrail bodies (2), then the guardrail bodies (2) are moved and fixed through moving the mobile firmware (1) of each of the guardrail bodies (2) along a desired route, so as to complete arrangement of the guardrail bodies (2).

4. The method, as recited in claim 1, wherein four universal wheels (4) are arranged under the mobile firmware (1), and each of the universal wheels (4) comprises a foot break (41) for fixing the guardrail bodies (2); a pair of handles (6) are symmetrically provided on external faces at a top portion of each of the guardrail bodies (2) for lifting the guardrail bodies (2) by worker hands.

5. The method, as recited in claim 1, wherein a solar power unit (9) and a caution light (7) are provided on each of the guardrail bodies (2) for warning.

6. A device for electric power construction warning, comprising: a guardrail body (2), a caution light (7) and a second hook (3), wherein a mobile firmware (1) is provided under the guardrail body (2); the second hook (3) is provided on a left side of the firmware (1), and a second ring (5) is provided on a right side of the firmware (1); a pair of handles (6) are symmetrically provided on external faces at a top portion of the guardrail body (2); a first ring (13) is provided on an external face at a bottom portion of the guardrail body (2); two roller supports (16) are separately provided on a left side of the guardrail body (2), and a roller (15) is provided on each of the roller supports (16); a warning strip (12) is wound on the roller (15), and one end of the warning strip (12) is connected to a first hook (10) through a connecting belt (11).

7. The device, as recited in claim 6, wherein the second hook (3) is vertically arranged with an opening thereof facing downwards, and the second ring (5) is horizontally arranged; the second ring (5) cooperates with the second hook (3) for connection.

8. The device, as recited in claim 6, wherein four universal wheels (4) are arranged under the mobile firmware (1), and each of the universal wheels (4) comprises a foot break (41).

9. The device, as recited in claim 6, wherein the caution light (7) is provided on a top of the guardrail body (2), and is covered by a shell (8); a solar power unit (9) is provided on a top of the shell (8), and is connected to the caution light (7).

10. The device, as recited in claim 6, wherein the caution light (7) comprises a switch.
